(19) United States
(12) Patent Application Publication
(10) Pub. No.: US 2010/0295016 A1
(43) Pub. Date: Nov. 25, 2010

(54) FLUORESCENT FIBER CONTAINING SEMICONDUCTOR NANOPARTICLES

(75) Inventors: Norio MURASE, Osaka (JP); Ping Yang, Osaka (JP); Masanori Ando, Osaka (JP)

Correspondence Address: KRATZ, QUINTOS & HANSON, LLP, 1420 K Street, N.W., 4th Floor, WASHINGTON, DC, 20005, US

(73) Assignee: NATIONAL INSTITUTE OF ADVANCED INDUSTRIAL SCIENCE AND TECHNOLOGY, Tokyo (JP)

(21) Appl. No.: 12/779,470

(22) Filed: May 13, 2010

(30) Foreign Application Priority Data
May 14, 2009 (JP) 2009-117166
Apr. 23, 2010 (JP) 2010-99421

(51) Int. Cl. H01L 33/40; H01L 21/30

(52) U.S. Cl. 257/13; 438/29; 257/E33.061; 257/E21.211; 977/762; 977/949

(57) ABSTRACT

The present invention provides a luminescent fiber, which retains a certain shape with assembled nanoparticles, and a method for producing the luminescent fiber. Specifically, the present invention provides a luminescent fiber comprising silicon and semiconductor nanoparticles having a mean particle size of 2 to 12 nm, the luminescent fiber having a diameter of 20 nm to 2 μm, a length of 40 nm to 500 μm, an aspect ratio of 2 to 1,000, and photoluminescence efficiency of not less than 5%.

### TECHNICAL FIELD

The present invention relates to a fiber that contains semiconductor nanoparticles, and emits luminescence.

### BACKGROUND ART

Nowadays, luminescent materials are widely used for three applications, i.e., illumination, display materials, and various detecting devices, and support our daily lives. Examples of such luminescent materials include organic molecules, as well as phosphors that contain inorganic matrices in which transition element ions (transition-metal ions and/or rare earth ions) are dispersed. Recently, organic molecules have been increasingly used for electroluminescence (EL), and have also been used as fluorescence reagents for bio-applications.

In the last ten years, it has been discovered that semiconductor nanoparticles obtained by a solution method emit photoluminescence (PL) efficiently. Such semiconductor nanoparticles are drawing attention as a third phosphor that can be used in place of transition element ions and organic molecules. Typical examples of such semiconductor nanoparticles include Group II-VI compounds, such as cadmium selenide, cadmium telluride, zinc selenide, and the like. In addition to these examples, lead sulfide, lead selenide, Group III-V compounds (e.g., indium phosphide), and the like are known as semiconductor nanoparticles. These semiconductor nanoparticles have a diameter of approximately 2 to 12 nm, and a short emission decay time, and are capable of controlling emission wavelengths by changing particle diameters. In the present specification, when semiconductor nanoparticles have an imperfect spherical shape, i.e., a rugby ball shape (spheroid elongated in the symmetry axis direction), a pancake shape (flattened spheroid), or the like, the average of three axis lengths is defined as the diameter.

Such semiconductor nanoparticles have a large specific surface area because of their small particle sizes. In general, semiconductor nanoparticles have many defects (active sites) on their surface, and the defects cause radiationless deactivation. Accordingly, to attain high PL efficiency, deactivating active sites using a specific method is necessary, particularly when small particles such as nanoparticles are used. Further, the nanoparticles obtained by a solution method are difficult to handle as is, and thus, they must be stabilized in an appropriate matrix for industrial application.

For producing semiconductor nanoparticles, an organic solution method and an aqueous solution method by which cadmium selenide nanoparticles and cadmium telluride nanoparticles are typically produced, respectively, are known. It is important for semiconductor nanoparticles to have water dispersibility for use in the field of biotechnology, or for dispersion and stabilization in a glass matrix by a sol-gel method. The nanoparticles obtained by the organic solution method will have hydrophobicity. To make such nanoparticles water-dispersible, various chemical operations are required. During these chemical operations, reduction in PL efficiency, aggregation of the semiconductor nanoparticles, and the like are likely to occur. In contrast, there is an advantage to preparing nanoparticles by an aqueous solution method, because the nanoparticles prepared by an aqueous solution method originally have water dispersibility. Each surface of such semiconductor nanoparticles is coated with a surfactant. Surfactants containing sulfur such as thiols are preferred as the surfactant. The relationship of the PL efficiency with the type and amount of the surfactant used has been clarified (Patent Document 1).

It is also known that nanoparticles in a solution may spontaneously self-organize into an assembly. For example, when methanol, a poor solvent, is gradually added to a toluene solution in which CdSe nanoparticles are dispersed, the CdSe nanoparticles will precipitate to form a hexagonal superlattice structure (a crystal in which the nanoparticles are regularly arranged) (Non-Patent Document 1). Further, when PbS nanoparticles in which the surfactant has been partly removed from their surface are dispersed in a mixed solvent of hexane and octane, the resulting dispersion is added dropwise to a small gap formed on a substrate, and the solvent is evaporated, the nanoparticles will form a regular arrangement (Non-Patent Document 2). Regarding synthesis of CdTe nanoparticles in an aqueous solution, it has been reported that performing a reaction of a solution containing Cd ions and a surfactant (thioglycolic acid) under reflux to produce a fiber, and adding a NaHTe solution thereto will cause CdTe nanoparticles to foam inside the fiber (Non-Patent Document 3).

However, no reports have been found regarding the values of PL spectrum and PL efficiency in any of the above cases. In order to retain the PL efficiency of semiconductor nanoparticles, it is most important that the surfactant on the surface of the nanoparticles is maintained when the nanoparticles assemble, so as to avoid surface defect formation. Surfactants also prevent semiconductor nanoparticles from irregularly forming an aggregate in a solution. However, to obtain an assembly in which semiconductor nanoparticles are regularly arranged, the nanoparticles must be closely allocated therebetween. Therefore, a removal of at least a portion of the surfactant is generally allowed to proceed. If the surfactant is entirely removed, the nanoparticles immediately form an aggregate with an irregular arrangement; therefore, retaining some portion of the surfactant is advantageous. The production methods as such suffer from a significant reduction in PL efficiency. Further, the assemblies that have been reported so far contain no silicon, and thus, retaining the shape of the produced assemblies has been difficult.

It has been found that when photoluminescent semiconductor nanoparticles coated with silicon-containing glass are refluxed in an aqueous solution containing metal ions, a thiol and a surfactant, the PL efficiency increases and the PL wavelength shifts to the longer wavelength side. This phenomenon can be explained as follows. That is, the thiol decomposes under reflux, yielding sulfur ions, and the yielded sulfur ions diffuse inside the glass and coordinate with metal ions, thereby developing, in the glass, a cluster (size: 1 nm or less) in the vicinity of the nanoparticles. The clusters developed in the glass layer in the vicinity of the nanoparticles assemble with, the nanoparticles, and form glass beads having a composite structure. Then, electrons in an exciton formed in the semiconductor nanoparticles transfer to the clusters, reducing the quantum size effect. Thereby, the PL efficiency is assumed to increase and the PL wavelength to shift to the longer-wavelength side (Patent Document 2 and Non-Patent Document 4). Within such glass beads, the semiconductor nanoparticles are surrounded by a large number of clusters, and therefore exert far superior chemical resistance than semiconductor nanoparticles dispersed alone in water.

As above, glass beads having excellent chemical resistance and high PL efficiency have been known, but luminescent fibers that can retain high PL efficiency are not yet known.

### PRIOR ART

### Patent Documents

Patent Document 1: WO 2004/065296

Patent Document 2: WO 2009/028282

### Non-Patent Documents

Non-Patent Document 1: Talapin et al., Advanced Materials, vol. 13, p. 1868 (2001)

Non-Patent Document 2: Talapin et al., Science, vol. 310, p. 86 (2005)

Non-Patent Document 3: Niu et al., Angewante Chemie International Edition, vol. 45, p. 6462 (2006)

Non-Patent Document 4: Murase et al., Small, vol. 5, p. 800 (2009)

### SUMMARY OF THE INVENTION

### Problems to be Solved by the Invention

The object of the present invention is to provide a luminescent fiber, which retains a certain shape with assembled nanoparticles, and a method for producing the luminescent fiber.

### Means for Solving the Problems

The present inventors found that a fiber produced by a specific method does not lose its luminescence, and that the emission color can be adjusted by changing the reflux time. The present inventors further found that the shape of the luminescent fiber can be adjusted by changing the amounts of a metal ion other than silicon, a surfactant, and an alkoxide that are contained in a reflux solution. Namely, the luminescent fiber can be formed into a tube-shaped fiber with a tubular cavity, a fiber with a quadrangle cross-section, and the like. Based on these findings, the inventors accomplished the present invention. Since the luminescent fibers of the present invention contain silicon, the luminescent fibers have excellent shape stability.

Specifically, the present invention provides a luminescent fiber, a phosphor for bio-applications, which is obtained by utilizing the luminescent fiber, and a method for producing the luminescent fiber, as summarized below.

Item 1. A luminescent fiber comprising silicon and semiconductor nanoparticles having a mean particle size of 2 to 12 nm, the luminescent fiber having a diameter of 20 nm to 2 μm, a length of 40 nm to 500 μm, an aspect ratio of 2 to 1,000, and photoluminescence efficiency of not less than 5%.

Item 2. The luminescent fiber according to Item 1, which has a tube shape with a tubal cavity, the tubal cavity having a diameter that is 10% to 80% the diameter of the fiber.

Item 3. The luminescent fiber according to Item 1, which has a rod shape with a quadrangle cross-section.

Item 4. The luminescent fiber according to Item 1, wherein the semiconductor nanoparticles are dispersed in the fiber at a concentration of 0.0001 to 0.01 mol/L.

Item 5. The luminescent fiber according to Item 1, wherein the semiconductor nanoparticles are cadmium telluride.

Item 6. The luminescent fiber according to Item 1, wherein each of the semiconductor nanoparticles is coated with a thiol.

Item 7. The luminescent fiber according to Item 6, wherein the thiol is thioglycolic acid.

Item 8. The luminescent fiber according to Item 1, wherein a peak wavelength of a photoluminescence spectrum is 500 to 900 nm, and a full width at half maximum of the spectrum is 30 to 150 nm.

Item 9. The luminescent fiber according to Item 1, which shows electroluminescence.

Item 10. A phosphor for biotechnology applications, which is obtained by using the luminescent fiber of Item 1.

Item 11. A method for producing a luminescent fiber comprising semiconductor nanoparticles whose surfaces are coated with a silicon-containing layer, the method comprising the steps of:

(1) forming a coating layer on each surface of the semiconductor nanoparticles having a mean particle size of 2 to 12 nm by a sol-gel method using a silicon alkoxide;

(2) dispersing the coating layer-coated semiconductor nanoparticles obtained in step (1) at a concentration of 1×10⁻⁶ to 3×10⁻⁵ mol/L in an aqueous solution comprising 1×10⁻³ to 7×10⁻³ mol/L of alkoxide, 1×10⁻³ to 6×10⁻³ mol/L of thiol, and a compound containing a metal element other than silicon in an amount of 25 to 50 mol % relative to the thiol, followed by heating at 40 to 110° C.

Item 12. The method for producing a luminescent fiber according to Item 11, wherein the thiol is thioglycolic acid.

### EFFECT OF THE INVENTION

A luminescent fiber of the present invention is produced by coating semiconductor nanoparticles with a transparent glass layer containing silicon to form glass beads, and allowing the glass beads to spontaneously self-assemble by heating under specific conditions. Under some conditions, the fiber can be formed into a tube shape with a cavity. When the cavity of the tube is filled with a molecule having a pharmacological effect, the location of the molecule in vivo can be detected by the luminescence.

### BRIEF DESCRIPTION OF THE DRAWING

FIG. 1 is scanning electron micrographs of a tube-shaped luminescent fiber produced in Example 1.

FIG. 2 is scanning electron micrographs of a belt-like shaped luminescent fiber produced in Example 2.

FIG. 3 is scanning electron micrographs of a rod-shaped luminescent fiber produced in Example 3.

FIG. 4 is a fluorescence micrograph of a luminescent fiber produced in Example 4. Because it is an optical microscope, whose optical resolution is in the order of 1 μm, the diameter and shape cannot be accurately assessed from the figure.

FIG. 5 is an image in which an EL element obtained in Example 5 by applying a luminescent fiber onto an interdigitated electrode emits EL at an applied voltage of 36 V (electric field strength: 7.2×10⁶ V/m) (the image displayed by superimposing a photograph of the appearance that are obtained by an optical microscope and an image of EL at the same position). The deep-colored portion indicates a gold electrode (10 μm in width), and a light-colored portion indicates an interelectrode gap (5 μm in width). The portion to which the fiber is adhering between electrodes emits luminescence.

### BEST MODE FOR CARRYING OUT THE INVENTION

Hereinafter, the present invention is described in detail.

### I. Luminescent Fiber

A luminescent fiber of the present invention contains silicon and semiconductor nanoparticles having a mean particle size of 2 to 12 nm, the luminescent fiber having a diameter of about 20 nm to about 2 μm, a length of about 40 nm to about 500 μm, and an aspect ratio of about 2 to about 1,000. The semiconductor nanoparticles in the luminescent fiber are preferably coated with a silicon-containing layer. As described above, the luminescent fiber of the present invention has a fiber shape, and thus can emit EL when a voltage is applied in the longitudinal direction, unlike luminescent materials having a particle shape. This is an advantage that cannot be gained with known luminescent materials having a particle shape. In addition, when the fiber has a cavity (particularly, a tubal shape) thereinside, a desired substance can be filled inside the cavity, and distributed in vivo; the location of the distributed substance can be detected by the luminescent of the fiber.

Further, the PL efficiency of the luminescent fiber of the present invention is not less than 5%.

The luminescent fiber of the present invention is generally produced by preparing semiconductor nanoparticles, coating the semiconductor nanoparticles, and heating the coated semiconductor nanoparticles. Hereunder, the steps are described. As shown in the Examples, the luminescent fiber of the present invention can be produced without following the above procedure by, for example, omitting the heat treatment.

### Production of Semiconductor Nanoparticles

Semiconductor nanoparticles used in the present invention are preferably luminescent semiconductor nanoparticles that have water dispersibility, such as those belonging to the Group II-VI or III-V compound semiconductor that undergo direct transition and emit visible photoluminescence. Examples of the semiconductor nanoparticles include those having at least one element selected from the group consisting of zinc, cadmium, mercury, sulfur, selenium, tellurium, aluminum, gallium, indium, phosphorus, arsenic, antimony, and lead. Specific examples include cadmium sulfide, zinc selenide, cadmium selenide, zinc telluride, cadmium telluride, and the like. Preferred among these are zinc selenide and cadmium telluride, and particularly preferred is cadmium telluride. Other examples include lead sulfide; lead selenide; Group III-V semiconductors, such as indium phosphide, gallium arsenide; mixtures thereof; and the like.

The above semiconductor nanoparticles can be produced according to Li et al., Chemistry Letters, vol. 34, p. 92, (2005).

More specifically, for example, a Group-VI element compound is introduced under an inert atmosphere into an alkaline aqueous solution in which a water-soluble compound containing a Group-II element and a surfactant are dissolved, thereby obtaining Group II-VI semiconductors. A Group-VI element compound can also be used in the form of a gas.

Preferable as a water-soluble compound containing a Group II element is perchlorate. For example, cadmium perchlorate can be used when the Group II element is cadmium. The concentration of the water-soluble compound containing a Group II element in an aqueous solution is usually within the range of about 0.001 to about 0.05 mol/L, preferably about 0.01 to about 0.02 mol/L, more preferably about 0.013 to about 0.018 mol/L.

As surfactants, those containing a thiol group, which is a hydrophobic group, and a hydrophilic group are preferable. Examples of hydrophilic groups include anionic groups such as carboxyl groups and the like, cationic groups such as amino groups and the like, and hydroxyl groups and the like. Of these, anionic groups such as carboxyl groups and the like are particularly preferable. Specific examples of the surfactants include thioglycolic acid (TGA), thioglycerol, mercaptoethylamine, and the like. Of these, TGA is preferred. The amount of the surfactant used is generally about 1 to about 2.5 mol, preferably about 1 to about 1.5 mol, per 1 mol of Group II element ions contained in an aqueous solution. When the amount of surfactant used exceeds the upper limit of the above-mentioned range, or is lower than the lower limit thereof, the PL efficiency of the obtained semiconductor nanoparticles is prone to decrease.

Usable as a Group VI element compound are, for example, Group VI element hydrides and the like. Hydrogen telluride can be used when the Group VI element is tellurium. Other than the above, sodium hydrogen telluride, which is obtained through a reaction between hydrogen telluride and sodium hydroxide, can serve as an aqueous solution. The Group VI element compound is used in such a manner that the amount of Group VI element ions is generally about 0.3 to about 1.5 mol, preferably about 0.4 to about 0.9 mol, per 1 mol of Group II ions.

It is preferable to use high-purity water for producing semiconductor nanoparticles. In particular, it is preferable to use ultra-pure water in which the specific resistance is 18 MΩ·cm or more and the total amount of organic compound (TOC) in the water is 5 ppb or less, more preferably 3 ppb or less. By using such high-purity water to sufficiently wash a reaction container or the like, and also using it as a reaction solvent, semiconductor nanoparticles with excellent photoluminescent performance can be obtained.

The above-described reaction can generally be carried out by bubbling, under an inert atmosphere, a gaseous Group VI element compound in an aqueous solution in which a water-soluble compound containing a Group II element and a surfactant are dissolved. The reaction can also be carried out by allowing a gaseous Group VI compound to react with a sodium-hydroxide solution to yield an aqueous solution, and injecting the yielded aqueous solution using a syringe or the like into an aqueous solution in which a water-soluble compound containing a Group II element and a surfactant are dissolved.

There is no limitation to the inert gas, insofar as the gas does not affect the reaction. Preferable examples of the inert gas include argon gas, nitrogen gas, helium gas, and the like.

The above-described reaction can usually be performed at room temperature (for example, about 10° C. to about 30° C.). The pH of the aqueous solution is preferably about 10 to about 12, and more preferably 10.5 to 11.5. The reaction is usually completed within about 10 minutes after the introduction of the Group VI compound.

Thereafter, the refluxing in an open-air environment, and thereby, an aqueous solution can be obtained in which semiconductor nanoparticles of the desired size are dispersed.

The mean particle size of the thus-obtained semiconductor nanoparticles is generally in the range of about 2 to about 12 nm, preferably about 2 to about 8 nm, and more preferably about 3 to about 7 nm. The mean particle size can be adjusted according to the reflux time. The mean particle size can be measured, for example, with a transmission electron microscope. Alternatively, when the composition of the semiconductor is known, the mean particle size can also be calculated from the fluorescence peak wavelength. In order to obtain semiconductor nanoparticles that emit monochromatic light, the reflux time is kept constant, and the standard deviation of the particle size distribution is adjusted to 20% or less, preferably 15% or less of the mean particle size.

For example, when cadmium telluride or zinc selenide is used, the particle size is about 2 to about 5 nm. The particle size can be enlarged by increasing the reflux time. The particle size determines the color of the photoluminescence emitted from the semiconductor nanoparticles, and particles with smaller sizes emit shorter wavelengths of light. When the particle diameters of semiconductor nanoparticles are made uniform, monochromatic light can be obtained.

The thus-obtained aqueous solution (aqueous dispersion) of semiconductor nanoparticles usually contains a Group II element ion that was used as a starting material, a surfactant, and the like. This aqueous solution of semiconductor nanoparticles can be used for dispersion in an inorganic matrix, and by drying, a luminescent material (phosphor) can be obtained.

The semiconductor nanoparticles contained in the aqueous solution can be separated according to their particle size. For example, utilizing the fact that larger semiconductor nanoparticles have a lower solubility, the nanoparticles are precipitated in order of size, starting with the largest ones, by adding, as a poor solvent, alcohol such as isopropanol or ketone such as acetone to the aqueous solution of the nanoparticles; thereafter, the resulting solution can be centrifuged for separation.

When the thus-refined semiconductor nanoparticles are redispersed in water to yield an aqueous solution, the refined nanoparticles are imparted with a high PL efficiency. The aqueous solution as such is stable to some extent. However, the addition of a water-soluble compound containing a Group II element and a surfactant to the aqueous solution can improve the stability of the aqueous solution, preventing the aggregation of particles; thereby, the PL efficiency can be retained. The type of Group II element compound may be selected from those exemplified above for the aqueous solution used for producing the Group II-VI semiconductor nanoparticles; the concentration of the compound, the amount of the surfactant, the pH of the aqueous solution, and the like may be adjusted to fall within the ranges mentioned above for the aqueous solution used for producing the Group II-VI semiconductor nanoparticles.

Specifically, an aqueous solution with a pH ranging from about 10 to about 12, preferably about 10.5 to about 11.5, is suitable. More specifically, the aqueous solution contains Group II-VI semiconductor nanoparticles (about 1×10⁻⁷ to about 3×10⁻⁶ mol/L, preferably about 3×10⁻⁷ to about 2×10⁻⁶ mol/L), a water-soluble compound containing a Group II element as a starting material for the Group II-VI semiconductor nanoparticles (Group II element ion) (about 0.001 to about 0.05 mol/L, preferably about 0.01 to about 0.02 mol/L, and more preferably about 0.013 to about 0.018 mol/L), and a surfactant (about 0.5 to about 5 mol, preferably about 1 to about 1.5 mol, per 1 mol of the Group II element ions contained in the aqueous solution).

In addition, semiconductor nanoparticles of cadmium selenide or the like can be produced in an organic solvent utilizing thermal decomposition of an organic metal. When the surfaces of such semiconductor nanoparticles are replaced with a thiol-containing surfactant, such as TGA or the like, the resulting particles are imparted with water dispersibility, and thus can be used as an aqueous solution of semiconductor nanoparticles. This is a known method described in Japanese Unexamined Patent Publication No. 2002-525394, Bawendi et al.

When zinc selenide nanoparticles are used, the PL efficiency is increased to about 35% by ultraviolet irradiation after production using TGA and the like as a surfactant according to the above method. Specifically, the production is performed according to the method described in Li et al., Colloids and Surfaces A, vol. 294, p. 33, (2007). In addition, indium phosphorus, gallium arsenide, and the like belonging to the III-V Group are also usable.

### Coating of Semiconductor Nanoparticles

Using the semiconductor nanoparticle dispersion obtained above, a layer is coated on each surface of the semiconductor nanoparticles by a sol-gel method using a metal alkoxide. In particular, when silicon alkoxide is used, a transparent glass layer containing silicon will be formed.

According to one embodiment of the method, a metal alkoxide is added to water in which semiconductor nanoparticles are dispersed, and the resulting product is alkalified and then stirred. This allows the hydrolyzed metal alkoxide to adhere to the surfaces of the semiconductor nanoparticles and coat their surfaces; thereby, semiconductor nanoparticles coated with a coating layer, such as a glass layer, are obtained.

When the constituent elements of semiconductor nanoparticles are dispersed in a semiconductor nanoparticle dispersion as described above, the constituent elements are spontaneously incorporated into the glass layer.

Specifically, a coating layer is formed on each surface of the semiconductor nanoparticles by a sol-gel method using an aqueous solution (composition) containing a metal alkoxide, a compound containing a metal element (in particular, a metal element other than silicon) that is used as a starting material for the semiconductor nanoparticles, a surfactant and water.

Examples of metals other than silicon include metals that are usable as a starting material for semiconductor nanoparticles, such as zinc, cadmium and mercury, which belong to Group II, and aluminum, gallium, indium, and the like that belong to Group III. Examples thereof also include lead, copper, and the like. Further, examples of compounds containing a metal other than silicon include salts of each metal, such as perchloric acid compounds, chlorides, acetates, and the like.

In the present invention, in spite of using the above-obtained aqueous dispersion of the semiconductor nanoparticles as is, the semiconductor nanoparticles may be separated from the dispersion and redispersed in water for use. Specifically, in light of the fact that semiconductor nanoparticles precipitate in order of size, starting with the largest particles, by adding a poor solvent, such as alcohol, ketone, or the like, to the semiconductor nanoparticle dispersion, particles that have a certain size may be separated by centrifugation.

Subsequently, a metal ion used as a component of a cluster and a substance that supplies a counterion of the component are used to produce a dispersion. Namely, for example, when cadmium telluride semiconductor nanoparticles are used, cadmium salts that supply cadmium ions, i.e., a component of cadmium telluride, and a thiol that supplies sulfur ions, preferably thioglycolic acid (TGA), are used to produce the dispersion. Then, a metal alkoxide is added to the dispersion and each of the semiconductor nanoparticles is coated with a glass layer; the elements are thereby incorporated into the glass layer.

These elements are assumed to grow into clusters by heating the glass-coated semiconductor nanoparticles. When an element different from the constituent elements of semiconductor nanoparticles is dispersed, a cluster, which is different from the cluster that contains the constituent elements of the semiconductor nanoparticles, can be developed. Thereby, glass beads are obtained.

The metal alkoxide used for conducting the coating is preferably silicon alkoxide, and preferable as the silicon alkoxide is a tetrafunctional silicon alkoxide such as tetramethoxy orthosilicate, tetraethoxy orthosilicate (TEOS), and the like. Such silicon alkoxide is represented by General Formula (I):

Si(OR¹)₄ (I),

wherein R¹ is a C₁₋₄ lower alkyl group.

In addition to the compound represented by General Formula (I) above, it is also possible to use trifunctional silicon alkoxide having an organic functional group such as aminopropyltriethoxysilane, mercaptopropyltrimethoxysilane, etc.; or to partially add the trifunctional alkoxide to tetrafunctional alkoxide. Here, the trifunctional silicon alkoxide is a compound represented by General Formula (II):

R³ₚ—Si(OR⁴)₄₋ₚ (II),

wherein R³ represents a C₁₋₄ lower alkyl group having an amino group, thiol group, or carboxyl group, R⁴ represents a C₁₋₄ lower alkyl group, and p is 1, 2, or 3. In the compound represented by General Formula (II), an organic functional group represented by R³ and an alkoxy group represented by OR⁴ are both combined with an Si atom. Among alkoxides, the compound is particularly referred to as a silane coupling agent.

In order to alkalify the solution, ammonia and sodium hydrate may be used. Ammonia is particularly preferably used.

### Heat Treatment

In the present invention, the above-obtained semiconductor nanoparticles whose surfaces are coated with a coating layer, such as a glass layer, are heated in a solution in which an alkoxide, a thiol, and a compound containing a metal element other than silicon are dispersed. Thereby, the luminescent fiber of the present invention, which would have been difficult to produce, can surprisingly efficiently be obtained.

Usable herein as the alkoxide, thiol, and compounds containing a metal element other than silicon are those mentioned above. It is preferable that the coated semiconductor nanoparticles obtained above are dispersed at a concentration of 1×10⁻⁶ to 3×10⁻⁶ mol/L, preferably 1.5×10⁻⁶ to 2×10⁻⁶ mol/L in an aqueous solution containing: alkoxide at a concentration of 1×10⁻³ to 7×10⁻³ mol/L, preferably 3×10⁻³ to 5×10⁻³ mol/L; thiol at a concentration of 1×10⁻³ to 6×10⁻³ mol/L, preferably 2×10⁻³ to 4×10⁻³ mol/L; and the compound containing a metal element other than silicon in an amount of 25 to 50 mol %, preferably 30 to 40 mol %, relative to thiol.

The shape of the luminescent fiber of the present invention is determined according to the concentrations of the above substances in the dispersion. For example, when CdTe nanoparticles as the semiconductor nanoparticles, TEOS as the alkoxide, and TGA as the thiol are employed, by adjusting the molar concentrations of each of the substances to the ranges shown in Table 1 below, the luminescent fiber is formed into a tube shape, a belt-like shape, or a rod shape.

TABLE 1
Molar concentration (unit: mol/L) of each substance
in solution and the shape of the obtained fiber

| Shape | Tube shape | Belt-like shape | Rod shape |
|---|---|---|---|
| CdTe nanoparticle/ | 1 to 3 | 10 to 30 | 4 to 8 |
| 10⁻⁶ | | | |
| TEOS | 0.001 to 0.0025 | 0.003 to 0.004 | 0.0045 to 0.007 |
| TGA | 0.001 to 0.002 | 0.004 to 0.006 | 0.002 to 0.004 |

In the molar concentration of the semiconductor nanoparticles shown in Table 1, “×10⁻⁶” is omitted as explained in the left column of Table 1. When cadmium is used as the metal element other than silicon, the molar concentration thereof is preferably 25 to 50 mol %, and more preferably 30 to 40 mol %, as shown in Table 1 in the molar concentration of TGA.

The concentration of the semiconductor nanoparticles can be calculated by comparing the absorption spectrum of nanoparticles with a reference value (for Group II-IV semiconductor nanoparticles, see William Yu et al., Chemistry of Materials, vol. 15, p. 2854 (2003), and Murase et al., Nanoscale Research Letters, vol. 2, p. 230 (2007)).

The pH of the solution used herein is preferably about 8 to about 10.5, and more preferably about 9 to about 10. The pH can be adjusted with the addition of sodium hydroxide.

The heating temperature is generally about 40° C. to about 110° C., preferably 70° C. to 110° C., and more preferably 80° C. to 90° C. By refluxing the aqueous solution at a temperature slightly lower than the boiling point, the excessive vaporization of a component such as ammonia can be prevented in an effective manner. The luminescent fiber can be produced only by refluxing the aqueous solution without relying on heating. However, the heat treatment can shorten the time that is necessary for producing the luminescent fiber while increasing the yield thereof. Longer heating times tend to produce longer luminescent fibers.

During heating, adhesion of the metal alkoxide to the surface of the glass layer newly occurs, which often causes a slight increase in the size of the glass bead. The PL wavelength shifts to the red side with time. Therefore, while monitoring this change, heating may be continued until the desired wavelength is obtained.

By the above heating process, the glass beads spontaneously self-assemble, thereby yielding, as a precipitate, a luminescent fiber having a certain shape depending on the concentrations of the substances in the solution.

The thus-obtained luminescent fiber of the present invention has a diameter of about 20 nm to about 2 μm, preferably about 100 nm to about 1 μm, a length of about 40 nm to about 500 μm, preferably about 500 nm to about 200 μm, and an aspect ratio of about 2 to about 1,000, preferably about 10 to about 100. The aspect ratio can be reduced by pulverizing the obtained luminescent fiber.

When the luminescent fiber of the present invention is formed into a tube shape, the luminescent fiber may have a tubal cavity with a diameter of about 10% to about 80%, preferably about 15% to about 50%, of the diameter of the luminescent fiber. The luminescent fiber in a rod shape may have a quadrangle cross-section. When in a belt-like shape, the surface of the luminescent fiber is not necessarily flat and may be curved backward.

The diameters of the rod-shaped luminescent fiber having a quadrangle cross-section of the present invention, and the belt-like shaped luminescent fiber of the present invention refer to the length of the long side (longer side) of their cross-section.

The thus-obtained luminescent fiber of the present invention shows a PL spectrum that is equivalent to that of the glass beads in an aqueous solution. In the PL spectrum, the peak wavelength is about 500 to about 900 nm, and preferably about 550 to about 700 nm; and the full width at half maximum of the spectrum is about 30 to about 150 nm, and preferably about 35 to about 100 nm. The PL efficiency of the luminescent fiber of the present invention is preferably not less than 5%, and more preferably not less than 10%. The term “photoluminescence (PL) efficiency” used herein is defined as the probability in which the luminescent fiber emits PL upon absorption of excitation light; the term is also sometimes referred to as external quantum efficiency. The luminescent fiber of the present invention scatters excitation light, and therefore, the PL efficiency can be more exactly measured with an integrating sphere. This measurement can be performed using a commercially available device (e.g., C9920-12, a product of Hamamatsu Photonics K.K.).

The absorption spectrum of the luminescent fiber of the present invention can be measured by suspending the luminescent fiber in water. In such a case, effects of scattering are seen, but can be disregarded due to the moderate increase towards the short wavelength, i.e., the absorbance at the first absorption peak wavelength of nanoparticles can be calculated from the spectrum, which is affected by scattering. The concentration of the semiconductor nanoparticles in the luminescent fiber can be estimated from the thus-calculated absorbance, molar absorbance coefficient, and the mass and specific gravity of the fiber dispersed. By suitably maintaining this concentration, the brightness of the luminescence can be retained, while maintaining an appropriate distance between the semiconductor nanoparticles. Further, the phenomenon called concentration quenching causes a transfer of excitation energy, preventing reduction in the PL efficiency. From such a viewpoint, the concentration of the semiconductor nanoparticles in the luminescent fiber is preferably 0.0001 to 0.01 mol/L, and more preferably 0.0005 to 0.005 mol/L.

### II. Applications of Luminescent Fiber

The luminescent fiber of the present invention has a high PL efficiency and narrow PL spectrum width. A luminescent fiber that has a tube shape can also be produced. When the inside of the tube-shaped luminescent fiber is filled with a molecule having a pharmacological effect, the location of the molecule in vivo can be detected by the luminescence. Therefore, the luminescent fiber is useful as a phosphor for bio-applications.

### EXAMPLES

Hereunder, the present invention is described in detail with reference to Examples. However, the present invention is not limited by the Examples.

### Production Example 1

CdTe nanoparticles each of whose surfaces is protected with thioglycolic acid (TGA) were produced in accordance with a known method (Li, Murase, Chemistry Letters, vol. 34, p. 92 (2005)). Specifically, cadmium perchlorate (hexahydrate, 1.095 g) was dissolved in 200 ml of water. To this, TGA was added as a surfactant in an amount of 1.25 times the moles of cadmium perchlorate. To the resulting product, 1 N aqueous solution of sodium hydroxide was added to adjust the pH to 11.4. After degassing for 30 minutes, hydrogen telluride gas was introduced under an inert atmosphere while stirring vigorously. After stirring for another 10 minutes, a condenser was attached for refluxing at about 100° C. Cadmium telluride particles were grown by refluxing, and in about 20 minutes, an aqueous solution in which TGA-coated CdTe nanoparticles emitting green PL (2.6 nm in diameter) was obtained. The PL efficiency of the nanoparticles emitting green PL was 24%.

Then, after the CdTe nanoparticles were precipitated, the particles were dispersed at a concentration of 3×10⁻⁵ mol/L in water containing 0.02 mol/L of TGA and 0.007 mol/L of cadmium perchlorate. Then, 4 ml of the resulting solution was collected, and 50 μL of ammonia water (6.25 wt. %), 100 μL of tetraethoxy orthosilicate (TEOS) were further added thereto, followed by stirring for 2 hours. Thereby, nanoparticles coated with a silica layer were obtained.

### Example 1

The silica-coated CdTe nanoparticles produced in Production Example 1 were dispersed at the molar concentration shown in Table 2 in an aqueous solution containing TEOS and TGA at the molar concentrations respectively shown in Table 2. Then, cadmium perchlorate was further dispersed at a molar concentration of 33% (0.0003 mol/L) of the TGA concentration. The resulting dispersion was refluxed at 90° C. for 2 hours to thereby yield a tube-shaped luminescent fiber having an average length of about 50 μm, and an aspect ratio of about 50 to about 200.

TABLE 2
Concentration of each substance in an aqueous
solution for forming a tube-shaped fiber

| | Tube shape, average |
|---|---|
| Shape | length: 50 μm |
| CdTe nanoparticles/10⁻⁶ | 2.5 |
| TEOS | 0.0022 |
| TGA | 0.001 |

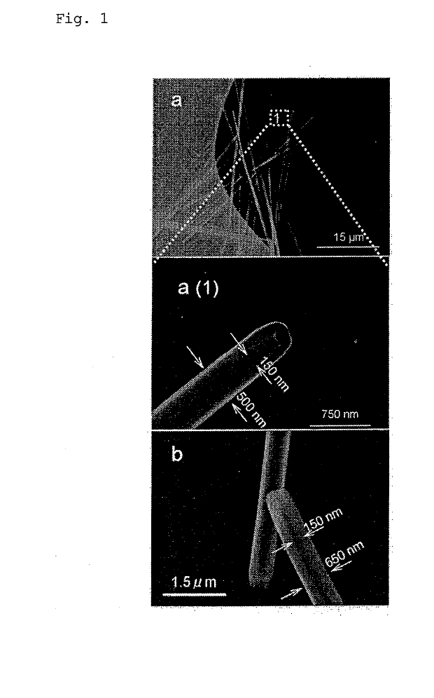

FIG. 1 shows the tube-shaped luminescent fiber observed with a scanning electron microscope. FIG. 1a(1) shows a partial enlargement of FIG. 1a. FIG. 1a(1) confirms that a hollow portion with a diameter of about 150 nm is formed inside the luminescent fiber having a diameter of about 500 nm, and that the luminescent fiber has a tube shape. This luminescent fiber has a tubal cavity thereinside, the tubal cavity having a diameter that is about 30% the diameter of the luminescent fiber. FIG. 1-b is an image of another portion of the fiber on an electron microscopic observation grid. FIG. 1-b confirms that a hollow portion with a diameter of about 150 nm is formed inside the luminescent fiber having a diameter of about 650 nm, and that the luminescent fiber is a tube shape. This luminescent fiber has a tubal cavity thereinside, the tubal cavity having a diameter that is about 23% the diameter of the luminescent fiber.

The PL efficiency of the tube-shaped fiber was measured at an excitation wavelength of 365 nm by an external quantum efficiency measurement system (C9920-12), a product of Hamamatsu Photonics K.K., using an integrating sphere. The result was 16%. The PL peak wavelength was 625 nm, and the full width at half maximum of the PL spectrum was 47 nm.

Further, the obtained tube-shaped luminescent fiber was suspended in water to measure the absorption spectrum. From the scattering curve, which smoothly increases towards the short wavelength side, the absorbance of the first absorption peak derived from the absorption of the nanoparticles was confirmed. Since the molar absorbance coefficient was known, by further using the weight and specific gravity of the fiber, the concentration of the semiconductor nanoparticles dispersed in the tube-shaped fiber was estimated as 0.002 mol/L. From the results, the average distance between the nanoparticles inside the tube-shaped fiber was calculated as about 9 nm. When this distance is about 5 nm, a transfer of excitation energy is established between the nanoparticles. This is a phenomenon called concentration quenching, by which the PL efficiency is significantly reduced. In the above fiber, the nanoparticles were dispersed at an appropriate interval, which enabled retention of the PL efficiency; further, a higher concentration of the nanoparticles in the fiber contributed to improve the brightness.

Subsequently, the relationship between the heating time and the average length of the luminescent fiber was measured. Under the conditions of this Example, a heating time of about 30 minutes yielded a luminescent fiber having a length of 5 μm; a heating time of about 1 hour yielded a luminescent fiber having a length of 20 μm; a heating time of about 2 hours yielded a luminescent fiber having a length of 50 μm as shown in Table 2; and the heating time of about 3 hours yielded a luminescent fiber having a length of 60 μm. The maximum PL efficiency of 25% was observed with a refluxing time of 1 hour. The PL peak wavelength at this time was 600 nm, and the full width at half maximum of the PL spectrum was 42 nm.

### Example 2

Silica-coated CdTe nanoparticles were produced as in Example 1.

Thereafter, the obtained silica-coated CdTe nanoparticles were dispersed at the molar concentration shown in Table 3 in an aqueous solution containing TEOS and TGA at the molar concentrations respectively shown in Table 3. Then, cadmium perchlorate was further dispersed at a molar concentration of 33% of the TGA concentration. The resulting dispersion was refluxed at 90° C. for 2 hours to thereby yield a belt-like shaped luminescent fiber with an average length of about 50 μm.

TABLE 3
Concentration of each substance in an aqueous
solution for forming a belt-like shaped fiber

| | Belt-like shape, average |
|---|---|
| Shape | length: 50 μm |
| CdTe nanoparticles/10⁻⁶ | 2.5 |
| TEOS | 0.0034 |
| TGA | 0.005 |

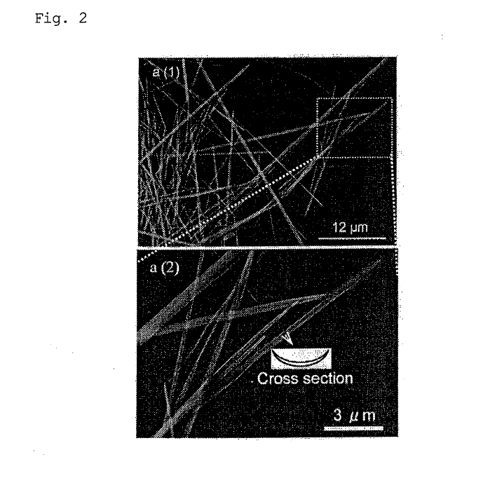

FIG. 2 shows the belt-like shaped luminescent fiber observed with a scanning electron microscope. FIG. 2a(2) is a partial enlargement of FIG. 2a(1). The portion labeled “Cross Section” in FIG. 2a(1) shows a cross-sectional view of the luminescent fiber. According thereto, the width is 0.5 μm, the total height of the curved portion is 0.1 μm, and the maximum thickness of the crescent-shaped cross-section is 30 nm. Therefore, the aspect ratio is about 100. The PL efficiency of the belt-like shaped luminescent fiber was measured at an excitation wavelength of 365 nm. The result was 10%. The PL peak wavelength was 599 nm, and the full width at half maximum of the PL spectrum was 48 nm. The concentration of the semiconductor nanoparticles dispersed in the belt-like shaped luminescent fiber was estimated as 0.004 mol/L.

Furthermore, composition analysis was conducted using an Energy Dispersive X-ray Fluorescence Spectrometer. The results reveal that the molar ratio of S/Cd is 1.55, and Si/Cd is 0.58, which confirmed that silicon was contained in the luminescent fiber.

When the refluxing time was decreased to 1 hour, the PL peak wavelength was 585 nm, and the full width at half maximum of the PL spectrum was 50 nm. When the refluxing time was 3 hours, the PL peak wavelength was 619 nm, and the full width at half maximum of the PL spectrum was 48 nm.

### Example 3

Silica-coated CdTe nanoparticles were produced as in Example 1.

Thereafter, the obtained silica-coated CdTe nanoparticles were dispersed at the molar concentration shown in Table 4 in an aqueous solution containing TEOS and TGA at the molar concentrations respectively shown in Table 4. Then, cadmium perchlorate was further dispersed at a molar concentration of 33% of the TGA concentration. The resulting dispersion was refluxed for 2 hours at 90° C. to thereby yield a rod-shaped luminescent fiber with an average length of about 40 μm.

TABLE 4
Concentration of each substance in an aqueous
solution for forming a rod-shaped fiber

| | Rod shape, average |
|---|---|
| Shape | length: 40 μm |
| CdTe nanoparticles/10⁻⁶ | 6.25 |
| TEOS | 0.0056 |
| TGA | 0.0025 |

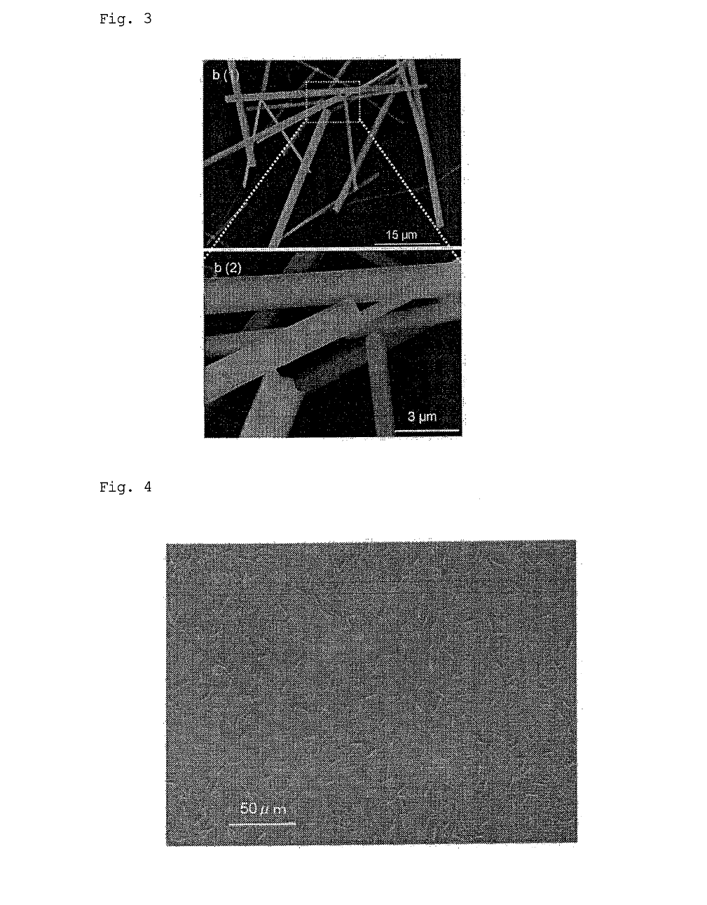

FIG. 3 shows the rod-shaped luminescent fiber observed with a scanning electron microscope. FIG. 3b(2) is a partial enlargement of FIG. 3b(1). FIG. 3b(2) confirms that the luminescent fiber has a quadrangle cross-section, and that no hollow portion was formed inside the fiber. The long side length of the rod-shaped luminescent fiber was about 300 nm to about 2 μm. Therefore, the aspect ratio was about 20 to about 130. The quadrangle of the cross-section is a rectangle, and the ratio of the length between the long side and the short side (long side/short side) is about 1.5. The belt-like shaped luminescent fiber was measured at an excitation wavelength of 365 nm. The result was 21%. The PL peak wavelength was 605 nm, and the full width at half maximum of the PL spectrum was 46 nm. The concentration of the semiconductor nanoparticles dispersed in the belt-like shaped luminescent fiber was estimated as 0.002 mol/L.

When the refluxing time was decreased to 1 hour, the PL peak wavelength was 591 nm, and the full width at half maximum of the PL spectrum was 47 nm.

### Example 4

Without refluxing, it was possible to produce a luminescent fiber over a longer period of time.

In an aqueous solution in which TGA had been dispersed at a concentration of 0.005 mol/L, and TEOS at a concentration of 0.02 mol/L, cadmium perchlorate was further dispersed at a molar concentration of 33% of the TGA concentration.

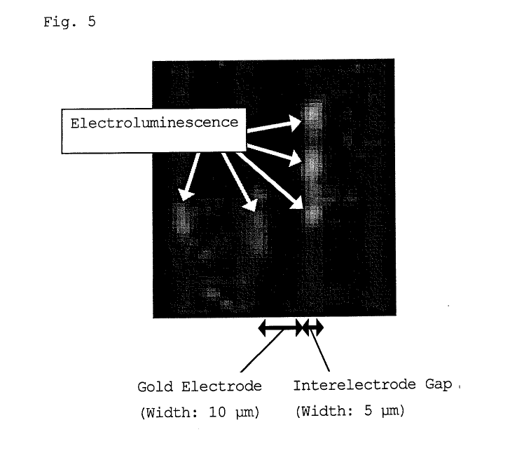

Thereafter, the glass-coated CdTe nanoparticles produced in Example 1 were dispersed at a concentration of 5×10⁻⁵ mol/L. The result was allowed to stand at a room temperature for two days. As a result, as shown in FIG. 4 of an observation image acquired by a fluorescence microscope, a luminescent fiber having a length of about 20 μm was produced. The PL peak wavelength at this time was 550 nm, and the full width at half maximum of the PL spectrum was 50 nm. The PL efficiency was 23%.

### Example 5

The rod-shaped luminescent fiber (PL color: red) produced in Example 3 was moistened with water, thinly applied on an interdigitated gold electrode (electrode width: 10 μm; interelectrode gap width: 5 μm, a product of BAS Inc.) that was provided on a glass substrate. The resulting product was dried in air at a room temperature for one day. The interdigitated electrode in which the fiber was applied was connected with a direct-current constant-voltage power supply, and the electroluminescence (EL) was analyzed using an optical microscope (a Nikon Eclipse 80i fluorescence microscope, which was used without excitation light).

When the applied voltage was increased from 0 V to 13 V (electric field strength: 2.6×10⁶ V/m), red EL was observed, and the EL intensity became higher upon increase of the applied voltage to 36 V (electric field strength: 7.2×10⁶ V/m), which was the upper limit of the power supply used. The EL color was red, which is the same color as the PL emitted by ultraviolet excitation. When the EL element emitting luminescence was observed in detail, the fiber emitting luminescence was recognized in the vicinity of the gap between the interdigitated electrodes, as shown in FIG. 5.

1. A luminescent fiber comprising silicon and semiconductor nanoparticles having a mean particle size of 2 to 12 nm, the luminescent fiber having a diameter of 20 nm to 2 μm, a length of 40 nm to 500 μm, an aspect ratio of 2 to 1,000, and photoluminescence efficiency of not less than 5%.

2. The luminescent fiber according to claim 1, which has a tube shape with a tubal cavity, the tubal cavity having a diameter that is 10% to 80% the diameter of the fiber.

3. The luminescent fiber according to claim 1, which has a rod shape with a quadrangle cross-section.

4. The luminescent fiber according to claim 1, wherein the semiconductor nanoparticles are dispersed in the fiber at a concentration of 0.0001 to 0.01 mol/L.

5. The luminescent fiber according to claim 1, wherein the semiconductor nanoparticles are cadmium telluride.

6. The luminescent fiber according to claim 1, wherein each of the semiconductor nanoparticles is coated with a thiol.

7. The luminescent fiber according to claim 6, wherein the thiol is thioglycolic acid.

8. The luminescent fiber according to claim 1, wherein a peak wavelength of a photoluminescence spectrum is 500 to 900 nm, and a full width at half maximum of the spectrum is 30 to 150 nm.

9. The luminescent fiber according to claim 1, which shows electroluminescence.

10. A phosphor for biotechnology applications, which is obtained by using the luminescent fiber of claim 1.

11. A method for producing a luminescent fiber comprising semiconductor nanoparticles whose surfaces are coated with a silicon-containing layer, the method comprising the steps of:
(1) forming a coating layer on each surface of the semiconductor nanoparticles having a mean particle size of 2 to 12 nm by a sol-gel method using a silicon alkoxide;
(2) dispersing the coating layer-coated semiconductor nanoparticles obtained in step (1) at a concentration of 1×10⁻⁶ to 3×10⁻⁵ mol/L in an aqueous solution comprising 1×10⁻³ to 7×10⁻³ mol/L of alkoxide, 1×10⁻³ to 6×10⁻³ mol/L of thiol, and a compound containing a metal element other than silicon in an amount of 25 to 50 mol % relative to the thiol, followed by heating at 40 to 110° C.

12. The method for producing a luminescent fiber according to claim 11, wherein the thiol is thioglycolic acid.
